(19) United States
(12) Patent Application Publication
(10) Pub. No.: US 2026/0194399 A1
(43) Pub. Date: Jul. 9, 2026

(54) ELECTRONIC CIRCUIT COMPONENT

(71) Applicant: YAZAKI CORPORATION, Tokyo (JP)

(72) Inventors: Hideki Mizuno, Kakegawa-shi (JP); Takayuki Maruno, Kakegawa-shi (JP); Masanori Nakamura, Kakegawa-shi (JP); Shinichi Kamura, Kakegawa-shi (JP)

(21) Appl. No.: 19/426,128

(22) Filed: Dec. 19, 2025

(30) Foreign Application Priority Data
Jan. 6, 2025 (JP) 2025-000100

(51) Int. Cl. G01K 7/22

(52) U.S. Cl. CPC G01K 7/22

(57) ABSTRACT

An electronic circuit component includes: a circuit board body having a plate shape and having a terminal insertion hole through which a terminal can be inserted; a temperature sensor provided on a surface of the circuit board body; and a heat transfer member that is provided in the circuit board body and transfers heat of the terminal inserted through the terminal insertion hole to the temperature sensor, in which the heat transfer member includes a base fixed to the circuit board body, a contact provided in the base and contactable with an outer peripheral surface of the terminal inserted through the terminal insertion hole, and a biasing member that biases the contact in a direction approaching the outer peripheral surface of the terminal from an outer side in a radial direction of the terminal.

### BACKGROUND OF THE INVENTION

### Field of the Invention

An embodiment of the present invention relates to an electronic circuit component.

Priority is claimed on Japanese Patent Application No. 2025-000100 filed in Japan on January 6, 2025, the content of which is incorporated herein by reference.

### Description of Related Art

There is known an electronic circuit component that detects a temperature of a terminal inserted into a hole formed in a circuit board with a sensor provided in the circuit board.

### Prior art document

### Patent document

Patent Document 1: Japanese Unexamined Patent Application, First Publication No. 2020-98776

### SUMMARY OF THE INVENTION

Incidentally, in an electronic circuit component, it is desired to detect a temperature of a terminal with a simple constitution, for example.

An embodiment provides an electronic circuit component that is easy to detect a temperature of a terminal.

An electronic circuit component of an embodiment includes: a circuit board body having a plate shape and having a terminal insertion hole through which a terminal can be inserted; a temperature sensor provided on a surface of the circuit board body; and a heat transfer member that is provided in the circuit board body and transfers heat of the terminal inserted through the terminal insertion hole to the temperature sensor, in which the heat transfer member includes a base fixed to the circuit board body, a contact provided in the base and contactable with an outer peripheral surface of the terminal inserted through the terminal insertion hole, and a biasing member that biases the contact in a direction approaching the outer peripheral surface of the terminal from an outer side in a radial direction of the terminal.

According to the embodiment, a temperature of the terminal is easily detected.

### BRIEF DESCRIPTION OF THE DRAWINGS

FIG. 1 is a cross-sectional view illustrating an electronic circuit component of an embodiment.

FIG. 2 is a cross-sectional view illustrating a state in which a terminal is inserted into a circuit board in the electronic circuit component of the embodiment.

FIG. 3 is a cross-sectional view illustrating a state in which the terminal of the electronic circuit component of the embodiment is connected to a connection destination terminal

### DETAILED DESCRIPTION OF THE INVENTION

Hereinafter, an embodiment will be described with reference to the drawings. In the following description, constitutions having the same or similar functions are denoted by the same reference numbers. Redundant descriptions of these constitutions may be omitted. Note that constitutions described below do not limit the scope of the embodiment.

In the present disclosure, terms are defined as follows. A “connection” is not limited to a mechanical connection, and may include an electrical connection. That is, the term “connection” is not limited to a case where two elements that are connection targets are directly connected, and may include a case where two elements that are connection targets are connected with another element interposed therebetween.

### Embodiment

### 1. Constitution of electronic circuit component

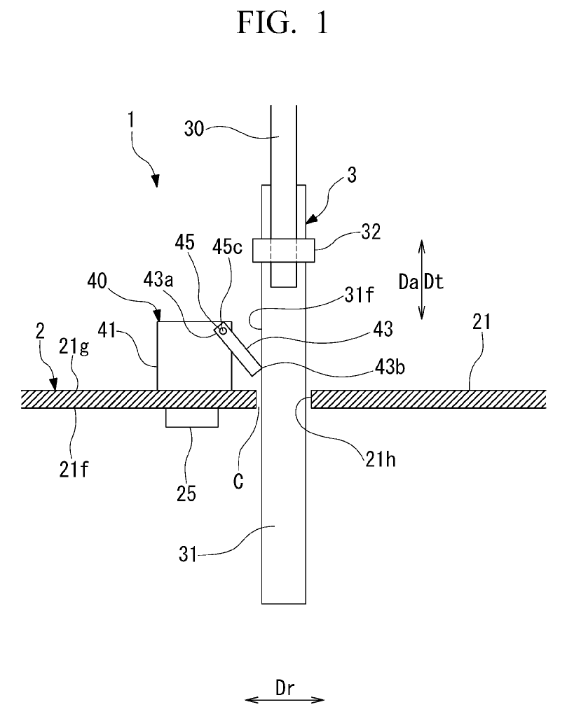

FIG. 1 is a cross-sectional view illustrating an electronic circuit component of an embodiment.

An electronic circuit component 1 illustrated in FIG. 1 includes a circuit board 2 and a terminal 3. The electronic circuit component 1 is applied to a charging inlet connected to an electric wire extending from a battery mounted on a vehicle such as an electric vehicle (EV), a hybrid electric vehicle (HEV), or a plug-in hybrid electric vehicle (PHEV).

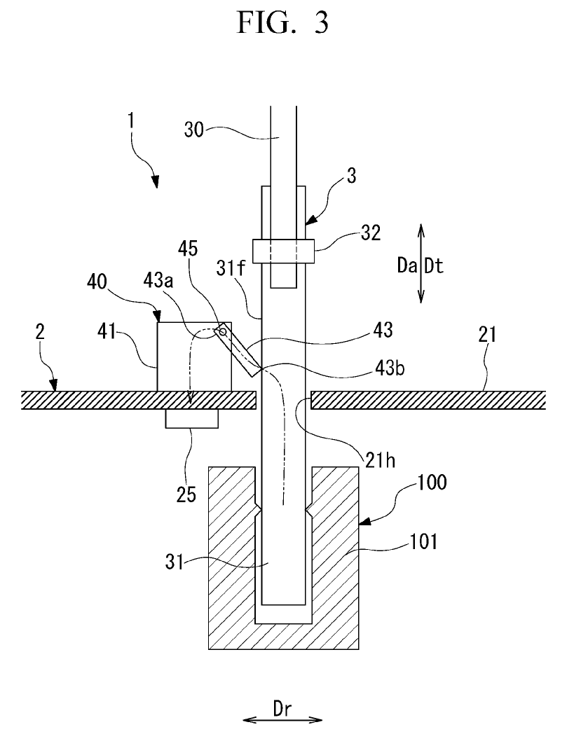

The terminal 3 of the electronic circuit component 1 is electrically connected to a connector 100 (see FIG. 3) of an external device. In the present disclosure, the “external device” is an electrical device existing outside the electronic circuit component 1. The external device is, for example, a battery unit mounted on a vehicle or an inverter for driving a motor of a vehicle. However, the external device is not limited to these examples.

### 2. Circuit board

The circuit board 2 includes a circuit board body 21, a temperature sensor 25, and a heat transfer member 40.

### Circuit board body

The circuit board body 21 has a plate shape and is a so-called printed circuit board (PCB). The circuit board body 21 is made of a material having electrical insulation, and a predetermined circuit pattern is formed on a surface thereof. Various electronic components (not shown) are mounted on the surface of the circuit board body 21. A terminal insertion hole 21h through which the terminal 3 to be described later is inserted is formed in the circuit board body 21. The terminal insertion hole 21h penetrates the circuit board body 21 in a plate thickness direction Dt of the circuit board body 21. Note that, in FIG. 1, one terminal insertion hole 21h is formed in the circuit board body 21. However, the number of terminal insertion holes 21h is not limited to one, and may be two or more.

### Temperature sensor

The temperature sensor 25 detects a temperature of the terminal 3 to be described later. The temperature sensor 25 is, for example, a thermistor. The temperature sensor 25 is mounted on a surface 21f facing one side in the plate thickness direction Dt of the surfaces of the circuit board body 21. The temperature sensor 25 is mounted on the surface 21f around the terminal insertion hole 21h. The surface 21f is an example of a first surface.

### Heat transfer member

The heat transfer member 40 transmits heat of the terminal 3 inserted through the terminal insertion hole 21h to the temperature sensor 25. The heat transfer member 40 is provided on a surface 21g facing another side in the plate thickness direction Dt of the surfaces of the circuit board body 21. The surface 21g is an example of a second surface.

The heat transfer member 40 includes a base 41, a contact 43, and a biasing member 45.

The base 41 is fixed to the surface 21g of the circuit board body 21. The base 41 is preferably formed of a material having as high thermal conductivity as possible, such as copper, aluminum, iron, or the like. The base 41 is formed to rise from the surface 21g. The base 41 is provided at a position overlapping the temperature sensor 25 as viewed in the plate thickness direction Dt.

The contact 43 is supported by the base 41. The contact 43 is preferably formed of a material having as high thermal conductivity as possible, such as copper, aluminum, iron, or the like. The contact 43 is formed in an arm shape extending from a first end 43a connected to the base 41 toward a second end 43b opposite to the first end 43a as viewed in the plate thickness direction Dt. The second end 43b of the contact 43 extends toward an inner side of the terminal insertion hole 21h than an inner edge of the terminal insertion hole 21h. In the present embodiment, the contact 43 extends obliquely from the first end 43a toward the second end 43b so as to gradually approach the surface 21g of the circuit board body 21 in the plate thickness direction Dt. The second end 43b of the contact 43 can contact an outer peripheral surface 31f of the terminal 3 inserted through the terminal insertion hole 21h.

The biasing member 45 is provided between the base 41 and the contact 43. The biasing member 45 biases the contact 43 in a direction approaching the outer peripheral surface 31f of the terminal 3 from an outer side in a radial direction Dr of the terminal 3 along the radial direction Dr of the terminal 3. In the present embodiment, the biasing member 45 is formed of a torsion spring extending in an axial shape. The biasing member 45 is provided so as to penetrate the base 41 and the first end 43a of the contact 43. The biasing member 45 rotatably supports the first end 43a of the contact 43 about a central axis 45c of the biasing member 45. The biasing member 45 is preferably made of a material having elasticity as a torsion spring, such as stainless steel, carbon steel, a nickel-titanium alloy, or the like.

### 3. Terminal

The terminal 3 is attached to a tip of an electric wire 30. The terminal 3 is made of a material having conductivity such as copper, aluminum, gold, silver, or the like. The terminal 3 integrally includes a terminal body 31 inserted through the terminal insertion hole 21h and a crimping portion 32 provided in the terminal body 31 and to which the tip of the electric wire 30 is crimped and fixed.

The terminal body 31 extends linearly in an axial direction Da. The terminal body 31 is inserted through the terminal insertion hole 21h in a state in which the axial direction Da is along the plate thickness direction Dt of the circuit board body 21. An outer diameter of the terminal body 31 is smaller than an inner diameter of the terminal insertion hole 21h. In a state in which the terminal body 31 is inserted through the terminal insertion hole 21h, a clearance C is formed between the inner edge of the terminal insertion hole 21h and the outer peripheral surface 31f of the terminal body 31.

### 4. Method for assembling electronic circuit component

In order to assemble the electronic circuit component 1 as shown in FIG. 1, the terminal body 31 of the terminal 3 is inserted through the terminal insertion hole 21h of the circuit board 2 provided with the temperature sensor 25 and the heat transfer member 40.

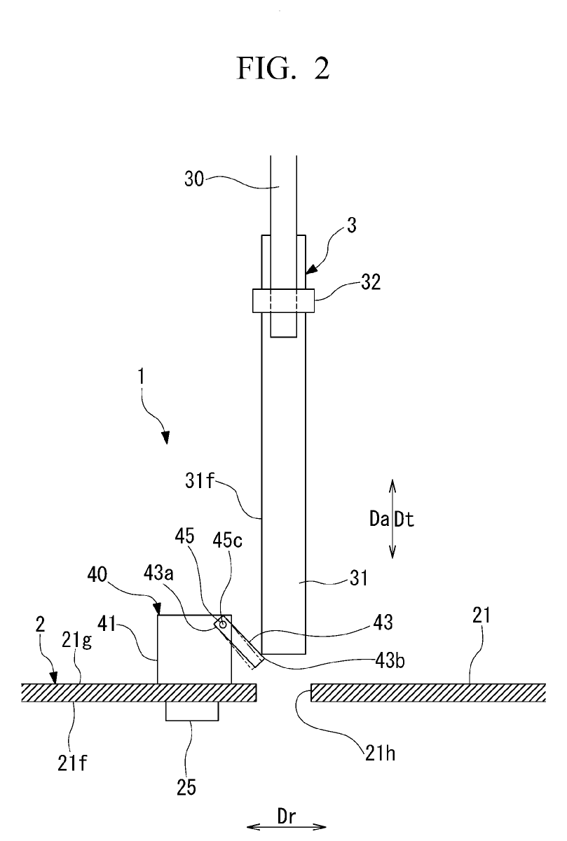

FIG. 2 is a cross-sectional view illustrating a state in which the terminal is inserted into the circuit board in the electronic circuit component of the embodiment.

As illustrated in FIG. 2, when the terminal 3 is inserted through the terminal insertion hole 21h, the second end 43b of the contact 43 is pressed by a tip of the terminal body 31, so that the contact 43 rotates in a direction in which the second end 43b approaches the surface 21g of the circuit board body 21. By the rotation of the contact 43, the biasing member 45 is twisted about its central axis 45c, so that the biasing member 45 biases the contact 43 in a direction in which the second end 43b of the contact 43 approaches the outer peripheral surface 31f of the terminal 3 along the radial direction Dr of the terminal 3. A biasing force of the biasing member 45 presses the second end 43b of the contact 43 against the outer peripheral surface 31f of the terminal 3.

### 5. Connection between terminal of electronic circuit component and external device

FIG. 3 is a cross-sectional view illustrating a state in which the terminal of the electronic circuit component of the embodiment is connected to a connection destination terminal.

As illustrated in FIG. 3, the terminal 3 of the electronic circuit component 1 as described above is connected to a connection destination terminal 101 of the connector 100 of the external device.

A temperature of the terminal 3 rises due to, for example, heat generated from the crimping portion 32 of the terminal 3 or a contact point between the connection destination terminal 101 and the terminal 3. The temperature (heat) of the terminal 3 is transferred to the circuit board body 21 via the contact 43, the biasing member 45, and the base 41 of the heat transfer member 40 in contact with the outer peripheral surface 31f of the terminal 3. The temperature sensor 25 detects a temperature of the base 41 of the heat transfer member 40 facing each other with the circuit board body 21 interposed therebetween.

### 6. Advantages

In the present embodiment, the electronic circuit component 1 includes the heat transfer member 40 that transfers the heat of the terminal 3 inserted through the terminal insertion hole 21h to the temperature sensor 25. The heat transfer member 40 includes the contact 43 that can come into contact with the outer peripheral surface 31f of the terminal 3, and the biasing member 45 that biases the contact 43 in the direction approaching the outer peripheral surface 31f of the terminal 3 along the radial direction of the terminal 3. With this constitution, in the heat transfer member 40 having a simple constitution, the contact 43 can be pressed against the outer peripheral surface 31f of the terminal 3 to transfer the heat of the terminal 3 to the temperature sensor 25. As a result, the temperature of the terminal 3 is easily detected.

In the present embodiment, the base 41 of the heat transfer member 40 is provided at the position overlapping the temperature sensor 25 as viewed in the plate thickness direction Dt of the circuit board body 21. With this constitution, the heat of the terminal 3 transferred via the heat transfer member 40 can be efficiently transferred to the temperature sensor 25.

In the present embodiment, the temperature sensor 25 is provided on the surface 21f of the circuit board body 21, and the heat transfer member 40 is provided on the surface 21g of the circuit board body 21. With this constitution, the heat of the terminal 3 transferred through the heat transfer member 40 can be efficiently transferred to the temperature sensor 25 while efficiently using space on the surfaces of the circuit board body 21.

In the present embodiment, the contact 43 has an arm shape extending from the first end 43a toward the second end 43b. With this constitution, the biasing member 45 can press the second end 43b of the contact 43 against the outer peripheral surface 31f of the terminal 3 with a simple constitution.

In the present embodiment, the biasing member 45 is a torsion spring. With this constitution, the heat transfer member 40 can have a simple and compact constitution.

In the present embodiment, the electronic circuit component 1 further includes the terminal 3 inserted through the terminal insertion hole 21h. With this constitution, in a state in which the terminal 3 is connected to the connector 100 of the external device, the temperature of the terminal 3 heated by the heat generated on the connector 100 side can be easily detected by the temperature sensor 25.

### 7. Modification examples

Next, several modification examples will be described. Note that a constitution other than those described below in each modification example is the same as the constitution of the above-described embodiment.

In the electronic circuit component 1 of the above-described embodiment, the temperature sensor 25 is provided on the surface 21f as the first surface. Further, in the electronic circuit component 1 of the above-described embodiment, the heat transfer member 40 is provided on the surface 21g as the second surface. Furthermore, the base 41 of the heat transfer member 40 is provided at the position overlapping the temperature sensor 25 as viewed in the plate thickness direction Dt. However, the constitution related to the electronic circuit component 1 is not limited to these constitutions. For example, the temperature sensor 25 may be disposed close to the heat transfer member 40 on the surface 21g on which the heat transfer member 40 is provided. That is, the temperature sensor 25 may be provided on the surface 21g as the first surface. On the other hand, the heat transfer member 40 may be provided on the surface 21f as the second surface.

In the electronic circuit component 1 of the above-described embodiment, the torsion spring is used as the biasing member 45. However, the constitution related to the biasing member 45 is not limited to this constitution. As the biasing member 45, a coil spring, a leaf spring, or the like may be used as long as the contact 43 can be biased in the direction approaching the outer peripheral surface 31f of the terminal 3 along the radial direction Dr of the terminal 3.

Further, although the heat transfer member 40 includes the contact 43 and the biasing member 45, for example, the contact 43 itself may be formed of a leaf spring, and the contact 43 may also serve as the biasing member 45.

Several embodiments and modification examples have been described above. However, the embodiments and the modification examples are not limited to the examples described above. For example, a plurality of embodiments may be implemented in combination with each other.

### REFERENCE SIGNS LIST

1 electronic circuit component

2 circuit board

3 terminal

21 circuit board body

21f surface (first surface, second surface)

21g surface (second surface, first surface)

21h terminal insertion hole

25 temperature sensor

31f outer peripheral surface

40 heat transfer member

41 base

43 contact

43a first end

43b second end

45 biasing member

What is claimed is:

1. An electronic circuit component comprising:
a circuit board body having a plate shape and having a terminal insertion hole through which a terminal can be inserted;
a temperature sensor provided on a surface of the circuit board body; and
a heat transfer member that is provided in the circuit board body and transfers heat of the terminal inserted through the terminal insertion hole to the temperature sensor, wherein
the heat transfer member includes
a base fixed to the circuit board body,
a contact provided in the base and contactable with an outer peripheral surface of the terminal inserted through the terminal insertion hole, and
a biasing member that biases the contact in a direction approaching the outer peripheral surface of the terminal from an outer side in a radial direction of the terminal.

2. The electronic circuit component according to claim 1, wherein
the base is provided at a position overlapping the temperature sensor when viewed from a plate thickness direction of the circuit board body.

3. The electronic circuit component according to claim 2, wherein
the temperature sensor is provided on a first surface on one side in the plate thickness direction of surfaces of the circuit board body, and
the heat transfer member is provided on a second surface on another side in the plate thickness direction of the surfaces of the circuit board body.

4. The electronic circuit component according to claim 1, wherein
the contact has an arm shape extending from a first end rotatably connected to the base toward a second end contactable with the outer peripheral surface of the terminal.

5. The electronic circuit component according to claim 4, wherein
the biasing member is a torsion spring that biases the first end of the contact such that the second end of the contact rotates in a direction approaching toward the outer peripheral surface of the terminal.

6. The electronic circuit component according to claim 1, further comprising
the terminal inserted through the terminal insertion hole.
